(19) United States
(12) Patent Application Publication
(10) Pub. No.: US 2024/0334741 A1
(43) Pub. Date: Oct. 3, 2024

(54) DISPLAY DEVICE

(71) Applicant: Sharp Display Technology Corporation, Kameyama City, Mie (JP)

(72) Inventors: Tadayoshi MIYAMOTO, Kameyama City, Mie (JP); Sohtaroh TANAKA, Kameyama City, Mie (JP); Fumie YASHIRO, Kameyama City, Mie (JP)

(21) Appl. No.: 18/291,047

(22) PCT Filed: Oct. 11, 2021
(86) PCT No.: PCT/JP2021/037611

§ 371 Date: Jan. 22, 2024

(51) Int. Cl. H10K 59/121; H10K 59/80

(52) U.S. Cl. CPC H10K 59/1213; H10K 59/871

(57) ABSTRACT

A display device includes: a resin substrate, and a thin film transistor layer, wherein in the thin film transistor layer, a first thin film transistor and a second thin film transistor are provided for each of subpixels. The first thin film transistor includes a first semiconductor layer formed of polysilicon, a first gate electrode provided on the resin substrate side of the first semiconductor layer via a first gate insulating film, and a metal layer provided on a side opposite to the resin substrate side of the first semiconductor layer via a first interlayer insulating film. The second thin film transistor includes a second semiconductor layer formed of an oxide semiconductor, and a second gate electrode provided on a side opposite to the resin substrate of the second semiconductor layer via a second gate insulating film.

### TECHNICAL FIELD

The disclosure relates to a display device.

### BACKGROUND ART

In recent years, as a display device replacing a liquid crystal display device, a self-luminous organic electroluminescence (hereinafter also referred to as “EL”) display device using an organic EL element has attracted attention. In the organic EL display device, a plurality of thin film transistors (hereinafter also referred to as “TFTs”) are provided for each subpixel being the smallest unit of an image. Well known examples of a semiconductor layer constituting the TFT include a semiconductor layer made of polysilicon having high mobility, and a semiconductor layer made of an oxide semiconductor with a low leakage current such as In—Ga—Zn—O.

For example, PTL 1 discloses a display device having a hybrid structure in which a first TFT using a polysilicon semiconductor and a second TFT using an oxide semiconductor are formed on a substrate.

### CITATION LIST

### Patent Literature

PTL 1: JP 2020-17558 A (FIG. 5 and FIG. 6)

### SUMMARY

### Technical Problem

As an organic EL display device, there is proposed a flexible organic EL display device using a resin substrate instead of a glass substrate which has been used in the related art. Note that a resin substrate contains a lot of impurity ions. Accordingly, for example, in the display device having the hybrid structure disclosed in PTL 1, when a resin substrate is used as a TFT substrate and the TFT being operated, impurity ions in the resin substrate are diffused, which may adversely affect the first TFT using a polysilicon semiconductor on the side near the resin substrate. As a result, the characteristics of the first TFT become unstable, so that the display quality degrades.

The disclosure has been conceived in view of the above point, and an object thereof is to stabilize characteristics of a TFT using a polysilicon semiconductor in a display device having a hybrid structure using a resin substrate.

### Solution to Problem

In order to accomplish the above object, a display device according to the disclosure includes a resin substrate and a thin film transistor layer provided on the resin substrate. In the thin film transistor layer, a first thin film transistor including a first semiconductor layer formed of polysilicon and a second thin film transistor including a second semiconductor layer formed of an oxide semiconductor are provided for each of subpixels constituting a display region. The first thin film transistor includes the first semiconductor layer in which a first conductor region and a second conductor region are defined to be separated from each other and a first channel region is defined between the first conductor region and the second conductor region, a first gate electrode provided on the resin substrate side of the first channel region via a first gate insulating film, a metal layer provided on a side opposite to the resin substrate side of the first semiconductor layer to overlap the first channel region via a first interlayer insulating film, and a first terminal electrode and a second terminal electrode provided to be separated from each other on a side opposite to the resin substrate of the metal layer and electrically connected to the first conductor region and the second conductor region, respectively. The second thin film transistor includes the second semiconductor layer which is provided at a position farther from the resin substrate relative to the first semiconductor layer and in which a third conductor region and a fourth conductor region are defined to be separated from each other, a second gate electrode provided on a side opposite to the resin substrate of the second semiconductor layer via a second gate insulating film, and a third terminal electrode and a fourth terminal electrode provided to be separated from each other on a side opposite to the resin substrate of the second gate electrode and electrically connected to the third conductor region and the fourth conductor region, respectively.

### Advantageous Effects of Disclosure

According to the disclosure, in a display device having the hybrid structure using a resin substrate, characteristics of a TFT using a polysilicon semiconductor may be stabilized.

### BRIEF DESCRIPTION OF DRAWINGS

FIG. 1 is a plan view illustrating a schematic configuration of an organic EL display device according to a first embodiment of the disclosure.

FIG. 2 is a plan view of a display region of the organic EL display device according to the first embodiment of the disclosure.

FIG. 3 is a cross-sectional view of the display region of the organic EL display device according to the first embodiment of the disclosure.

FIG. 4 is an equivalent circuit diagram of a thin film transistor layer constituting the organic EL display device according to the first embodiment of the disclosure.

FIG. 5 is a cross-sectional view illustrating an organic EL layer constituting the organic EL display device according to the first embodiment of the disclosure.

FIG. 6 is a first cross-sectional view illustrating a method for manufacturing the organic EL display device according to the first embodiment of the disclosure.

FIG. 7 is a second cross-sectional view illustrating the method for manufacturing the organic EL display device according to the first embodiment of the disclosure.

FIG. 8 is a third cross-sectional view illustrating the method for manufacturing the organic EL display device according to the first embodiment of the disclosure.

FIG. 9 is a fourth cross-sectional view illustrating the method for manufacturing the organic EL display device according to the first embodiment of the disclosure.

FIG. 10 is a fifth cross-sectional view illustrating the method for manufacturing the organic EL display device according to the first embodiment of the disclosure.

FIG. 11 is a sixth cross-sectional view illustrating the method for manufacturing the organic EL display device according to the first embodiment of the disclosure.

FIG. 12 is a seventh cross-sectional view illustrating the method for manufacturing the organic EL display device according to the first embodiment of the disclosure.

FIG. 13 is an eighth cross-sectional view illustrating the method for manufacturing the organic EL display device according to the first embodiment of the disclosure.

FIG. 14 is a ninth cross-sectional view illustrating the method for manufacturing the organic EL display device according to the first embodiment of the disclosure.

FIG. 15 is a tenth cross-sectional view illustrating the method for manufacturing the organic EL display device according to the first embodiment of the disclosure.

FIG. 16 is an eleventh cross-sectional view illustrating the method for manufacturing the organic EL display device according to the first embodiment of the disclosure.

FIG. 17 is a twelfth cross-sectional view illustrating the method for manufacturing the organic EL display device according to the first embodiment of the disclosure.

FIG. 18 is a thirteenth cross-sectional view illustrating the method for manufacturing the organic EL display device according to the first embodiment of the disclosure.

FIG. 19 is a cross-sectional view of a thin film transistor layer constituting an organic EL display device according to a second embodiment of the disclosure.

### DESCRIPTION OF EMBODIMENTS

Embodiments of a technique according to the disclosure will be described below in detail with reference to the drawings. Note that the technique according to the disclosure is not limited to the embodiments to be described below.

### First Embodiment

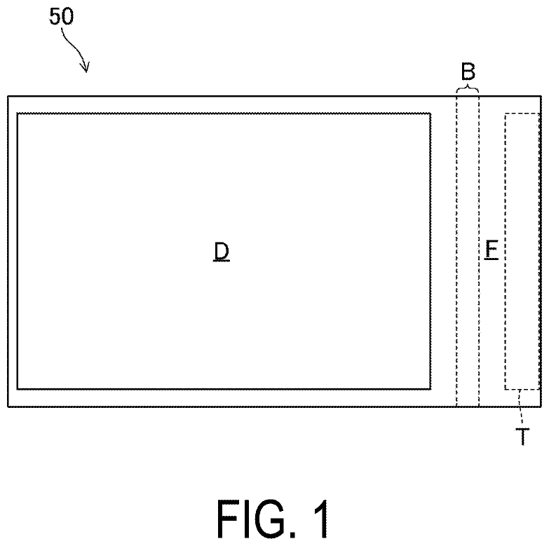

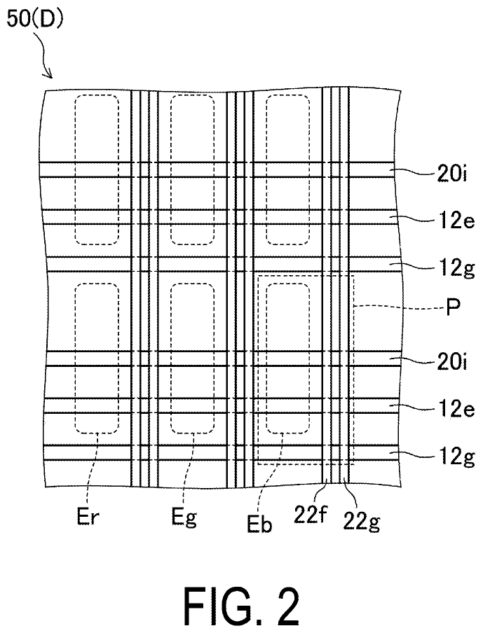

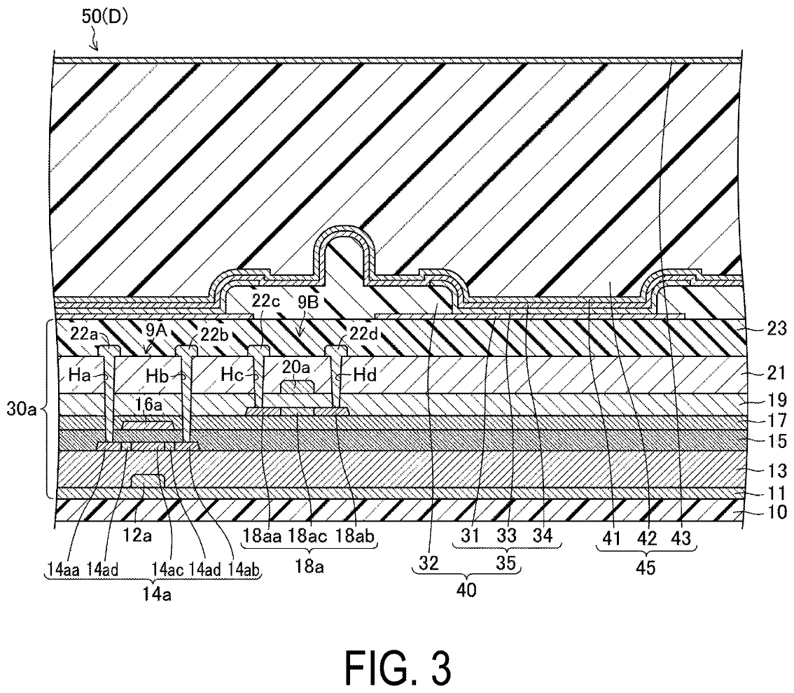

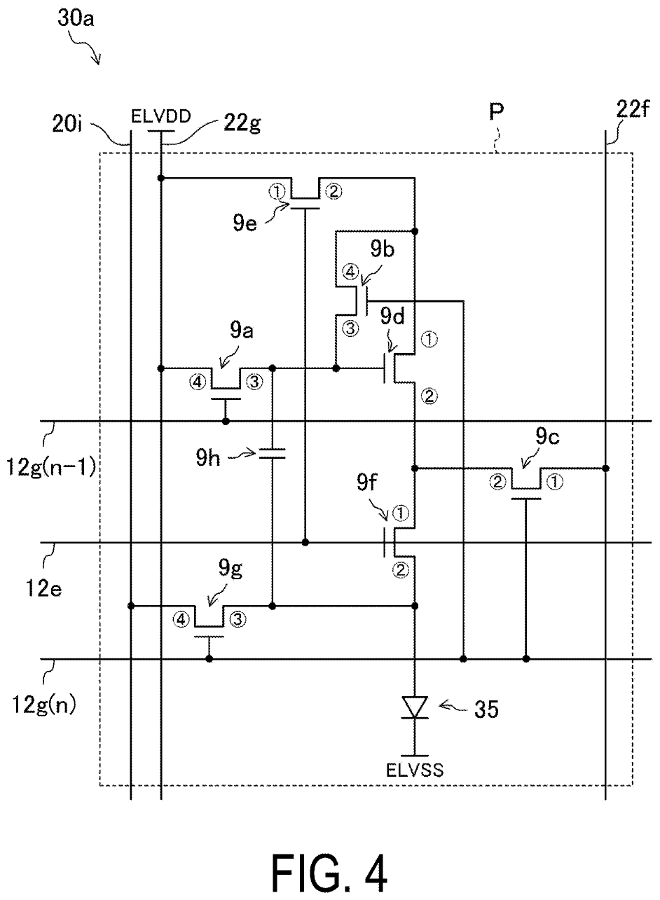

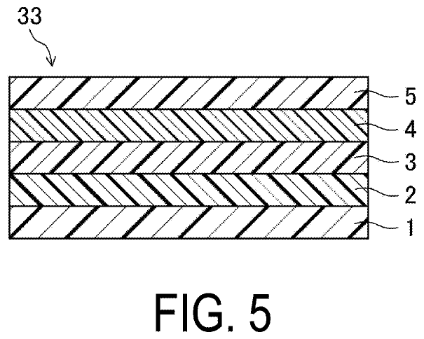

FIG. 1 to FIG. 18 illustrate a first embodiment of a display device according to the disclosure. Note that, in each of the following embodiments, an organic EL display device including an organic EL element layer is exemplified as a display device including a light-emitting element layer. Here, FIG. 1 is a plan view illustrating a schematic configuration of an organic EL display device 50 according to the present embodiment. FIG. 2 and FIG. 3 are a plan view and a cross-sectional view, respectively, of a display region D in the organic EL display device 50. FIG. 4 is an equivalent circuit diagram of a thin film transistor layer 30a constituting the organic EL display device 50. FIG. 5 is a cross-sectional view illustrating an organic EL layer 33 constituting the organic EL display device 50.

As illustrated in FIG. 1, the organic EL display device 50 includes, for example, the display region D having a rectangular shape and configured to display an image, and a frame region F provided around the display region D. Note that in the present embodiment, the display region D having the rectangular shape is exemplified, and the rectangular shape includes a substantial rectangular shape such as a shape whose sides are arc-shaped, a shape whose corners are arc-shaped, and a shape in which a part of a side has a notch.

As illustrated in FIG. 2, a plurality of subpixels P are arrayed in a matrix shape in the display region D. In addition, in the display region D, for example, a subpixel P including a red light-emitting region Er configured to display a red color, a subpixel P including a green light-emitting region Eg configured to display a green color, and a subpixel P including a blue light-emitting region Eb configured to display a blue color are provided adjacent to one another, as illustrated in FIG. 2. Note that one pixel is configured by, for example, the three adjacent subpixels P including the red light-emitting region Er, the green light-emitting region Eg, and the blue light-emitting region Eb in the display region D.

A terminal portion T is provided at the right end portion of the frame region F in FIG. 1. Further, as illustrated in FIG. 1, in the frame region F, a bendable bending portion B that can bend 1800 (in a U-shape) with the vertical direction in the drawing as a bending axis is provided between the display region D and the terminal portion T to extend in one direction (the vertical direction in the drawing).

As illustrated in FIG. 3, the organic EL display device 50 includes a resin substrate 10, the TFT layer 30a provided on the resin substrate 10, an organic EL element layer 40 provided as a light-emitting element layer on the TFT layer 30a, and a sealing film 45 provided to cover the organic EL element layer 40.

The resin substrate 10 is formed, for example, of a polyimide resin.

As illustrated in FIG. 3, the TFT layer 30a includes a base coat film 11 provided on the resin substrate 10, four first TFTs 9A, three second TFTs 9B, and one capacitor 9h (see FIG. 4) provided on the base coat film 11 for each subpixel P, and a flattening film 23 provided on each first TFT 9A, each second TFT 9B, and each capacitor 9h. As illustrated in FIG. 2, in the TFT layer 30a, a plurality of gate lines 12g are provided to extend parallel to each other in the horizontal direction in the drawing. As illustrated in FIG. 2, in the TFT layer 30a, a plurality of light emission control lines 12e are provided to extend parallel to each other in the horizontal direction in the drawing. As illustrated in FIG. 2, in the TFT layer 30a, a plurality of second initialization power source lines 20i are provided to extend parallel to each other in the horizontal direction in the drawing. As illustrated in FIG. 2, each light emission control line 12e is provided adjacent to each gate line 12g and also adjacent to each second initialization power source line 20i. As illustrated in FIG. 2, in the TFT layer 30a, a plurality of source lines 22f are provided to extend parallel to each other in the vertical direction in the drawing. As illustrated in FIG. 2, in the TFT layer 30a, a plurality of power source lines 22g are provided to extend parallel to each other in the vertical direction in the drawing. As illustrated in FIG. 2, each power source line 22g is provided adjacent to each source line 22f.

As illustrated in FIG. 3, the first TFT 9A includes a first gate electrode 12a provided on the base coat film 11; a first gate insulating film 13 provided to cover the first gate electrode 12a; a first semiconductor layer 14a provided on the first gate insulating film 13; a first interlayer insulating film 15 provided on the first semiconductor layer 14a; a metal layer 16a provided on the first interlayer insulating film 15, a second interlayer insulating film 17, a second gate insulating film 19, and a third interlayer insulating film 21 provided in sequence on the metal layer 16a; and a first terminal electrode 22a and a second terminal electrode 22b provided to be separated from each other on the third interlayer insulating film 21.

The base coat film 11, the first gate insulating film 13, the first interlayer insulating film 15, the second interlayer insulating film 17, the second gate insulating film 19, and the third interlayer insulating film 21 are each formed by, for example, a single-layer film of silicon nitride, silicon oxide or silicon oxynitride, or a layered film thereof. In this case, at least the second interlayer insulating film 17 and a portion of the second gate insulating film 19 on the side of a second semiconductor layer 18a described below are each formed of a silicon oxide film. The first gate insulating film 13 (for example, a layered film of a silicon oxide film (upper layer) of approximately 250 nm, a silicon nitride film (middle layer) of approximately 30 nm, and a silicon oxide film (lower layer) of approximately 100 nm) is thicker than the first interlayer insulating film 15 (for example, a single-layer film of a silicon oxide film of approximately 100 nm).

As illustrated in FIG. 3, the first gate electrode 12a is provided on the base coat film 11 to overlap a first channel region 14ac described below of the first semiconductor layer 14a, and is configured to control conduction between a first conductor region 14aa and a second conductor region 14ab described below of the first semiconductor layer 14a. In other words, as illustrated in FIG. 3, the first gate electrode 12a is provided on the resin substrate 10 side (lower side in the drawing) of the first channel regions 14ac via the first gate insulating film 13. As illustrated in FIG. 3, the first gate electrode 12a and a second gate electrode 20a to be described later have the same thickness and the same cross-sectional shape. The first gate electrode 12a is formed of the same material and in the same layer as signal wiring lines such as the gate lines 12g and the light emission control lines 12e.

The first semiconductor layer 14a is formed of, for example, polysilicon such as low temperature polysilicon (LTPS), and as illustrated in FIG. 3, includes the first conductor region 14aa and the second conductor region 14ab defined to be separated from each other, the first channel region 14ac defined between the first conductor region 14aa and the second conductor region 14ab, and a pair of low concentration impurity regions 14ad respectively provided at the first conductor region 14aa side of the first channel region 14ac and the second conductor region 14ab side thereof. The low concentration impurity regions 14ad are regions that are provided corresponding to end faces described below of both end portions on the first conductor region 14aa side and the second conductor region 14ab side of the metal layer 16a, and contain impurities at a concentration lower than that of the first conductor region 14aa and the second conductor region 14ab; that is, they are a so-called lightly doped drain (LDD) region.

As illustrated in FIG. 3, the metal layer 16a is provided on the opposite side to the resin substrate 10 side of the first semiconductor layer 14a (upper side in the drawing) in such a manner as to overlap the first channel region 14ac via the first interlayer insulating film 15. In addition, as illustrated in FIG. 3, end faces of both end portions of the metal layer 16a on the first conductor region 14aa side and the second conductor region 14ab side are inclined in a tapered shape in such a manner as to gradually project from the opposite side to the resin substrate 10 (the upper side in the drawing) toward the resin substrate 10 side (the lower side in the drawing). In this case, angles formed by the end faces of both the end portions of the metal layer 16a and the substrate surface are each, for example, approximately 20° to 40°. Angles formed by the substrate surface and end faces of both end portions of the first gate electrode 12a (the second gate electrode 20a to be described later) on the first conductor region 14aa side and the second conductor region 14ab side are each, for example, approximately 45° to 90°. The film thickness of the metal layer 16a is, for example, approximately 100 nm, and is smaller than that of the first gate electrode 12a and the second gate electrodes 20a (for example, approximately 200 nm), as illustrated in FIG. 3. As illustrated in FIG. 3, a width along a channel length direction (horizontal direction in the drawing) of the metal layer 16a is larger than a width along the channel length direction (horizontal direction in the drawing) of the first gate electrode 12a. The channel length direction is a direction parallel to a direction in which a current flows through the first channel region 14ac, and indicates the horizontal direction in FIG. 3. The metal layer 16a is not electrically connected to other electrodes, wiring lines, or the like and is electrically floating. As illustrated in FIG. 3, the second interlayer insulating film 17 is provided on the metal layer 16a to cover the metal layer 16a.

As illustrated in FIG. 3, the first terminal electrode 22a and the second terminal electrode 22b are provided on the opposite side to the resin substrate 10 side (upper side in the drawing) of the metal layer 16a, and are electrically connected to the first conductor region 14aa and the second conductor region 14ab, respectively, of the first semiconductor layer 14a through a first contact hole Ha and a second contact hole Hb formed in the layered film of the first interlayer insulating film 15, the second interlayer insulating film 17, the second gate insulating film 19, and the third interlayer insulating film 21.

As illustrated in FIG. 3, the second TFT 9B includes the second semiconductor layer 18a provided on the second interlayer insulating film 17, the second gate insulating film 19 provided on the second semiconductor layer 18a, the second gate electrode 20a provided on the second gate insulating film 19, the third interlayer insulating film 21 provided to cover the second gate electrode 20a, and a third terminal electrode 22c and a fourth terminal electrode 22d provided to be separated from each other on the third interlayer insulating film 21.

As illustrated in FIG. 3, the second semiconductor layer 18a is provided on the second interlayer insulating film 17, and includes, for example, a third conductor region 18aa and a fourth conductor region 18ab formed of oxide semiconductors based on In—Ga—Zn—O or the like and defined to be separated from each other, and a second channel region 18ac defined between the third conductor region 18aa and the fourth conductor region 18ab. As illustrated in FIG. 3, the second semiconductor layer 18a is provided at a position farther from the resin substrate 10 than a position of the first semiconductor layer 14a. Here, the In—Ga—Zn—O based semiconductor is ternary oxide of indium (In), gallium (Ga) and zinc (Zn), and a ratio (composition ratio) of In, Ga, and Zn is not limited to any specific value. The In—Ga—Zn—O based semiconductor may be an amorphous semiconductor or may be a crystalline semiconductor. Note that a crystalline In—Ga—Zn—O based semiconductor in which a c-axis is oriented substantially perpendicular to a layer surface is preferable as the crystalline In—Ga—Zn—O based semiconductor. In place of the In—Ga—Zn—O based semiconductor, another oxide semiconductor may be included. Examples of the another oxide semiconductor may include an In—Sn—Zn—O based semiconductor (for example, In₂O₃—SnO₂—ZnO; InSnZnO). The In—Sn—Zn—O based semiconductor is ternary oxide of indium (In), tin (Sn), and zinc (Zn). Examples of the another oxide semiconductor may include an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, cadmium oxide (CdO), a Mg—Zn—O based semiconductor, an In—Ga—Sn—O based semiconductor, an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, an In—Ga—Zn—Sn—O based semiconductor, InGaO₃(ZnO)₅, magnesium zinc oxide (MgₓZn₁₋ₓO), and cadmium zinc oxide (CdₓZn₁₋ₓO). Note that as the Zn—O based semiconductor, a semiconductor in a non-crystalline (amorphous) state of ZnO to which one kind or a plurality of kinds of impurity elements among group 1 elements, group 13 elements, group 14 elements, group 15 elements, group 17 elements, and the like are added, a polycrystalline state, or a microcrystalline state in which the non-crystalline state and the polycrystalline state are mixed, or a semiconductor to which no impurity element is added can be used.

As illustrated in FIG. 3, the second gate electrode 20a is provided to overlap the second channel region 18ac of the second semiconductor layer 18a, and is configured to control conduction between the third conductor region 18aa and the fourth conductor region 18ab of the second semiconductor layer 18a. To rephrase, as illustrated in FIG. 3, the second gate electrode 20a is provided on the opposite side to the resin substrate 10 side (upper side in the drawing) of (the second channel region 18ac) of the second semiconductor layer 18a via the second gate insulating film 19. The second gate electrode 20a is formed of the same material and in the same layer as other signal wiring lines such as the second initialization power source lines 20i. The third interlayer insulating film 21 is provided on the second gate electrode 20a to cover the second gate electrode 20a, as illustrated in FIG. 3.

As illustrated in FIG. 3, the third terminal electrode 22c and the fourth terminal electrode 22d are provided on the opposite side to the resin substrate 10 side (upper side in the drawing) of the second gate electrode 20a, and are electrically connected to the third conductor region 18aa and the fourth conductor region 18ab, respectively, of the second semiconductor layer 18a through a third contact hole He and a fourth contact hole Hd formed in the layered film of the second gate insulating film 19 and the third interlayer insulating film 21.

In the present embodiment, p-channel TFTs of a write TFT 9c, a drive TFT 9d, a power supply TFT 9e, and a light-emission control TFT 9f, which will be described below, are exemplified as the four first TFTs 9A including the first semiconductor layer 14a formed of polysilicon, and n-channel TFTs of an initialization TFT 9a, a compensation TFT 9b, and an anode discharge TFT 9g, which will be described below, are exemplified as the three second TFTs 9B including the second semiconductor layer 18a formed of the oxide semiconductor (see FIG. 4). Note that each of the four first TFTs 9A including the first semiconductor layer 14a formed of polysilicon may be the n-channel TFT. In the equivalent circuit diagram in FIG. 4, the first and second terminal electrodes 22a and 22b of each of the TFTs 9c, 9d, 9e, and 9f are indicated by circled numbers 1 and 2, respectively, and the third and fourth terminal electrodes 22c and 22d of each of the TFTs 9a, 9b, and 9g are indicated by circled numbers 3 and 4, respectively. In the equivalent circuit diagram in FIG. 4, the pixel circuit of the subpixel P in the n-th row and the m-th column is illustrated, but a part of the pixel circuit of the subpixel P in the (n−1)-th row and the m-th column is also included. In the equivalent circuit diagram in FIG. 4, the power source line 22g for supplying a high power supply voltage ELVDD also serves as a first initialization power source line, but the power source line 22g and the first initialization power source line may be provided separately. The same voltage as that of a low power supply voltage ELVSS is input to the second initialization power source line 20i, but is not limited thereto; a voltage that is different from the low power supply voltage ELVSS and turns off an organic EL element 35 described below may be input.

As illustrated in FIG. 4, in each subpixel P, the gate electrode of the initialization TFT 9a is electrically connected to the gate line 12g(n−1) of the previous stage ((n−1)-th stage), the third terminal electrode of the initialization TFT 9a is electrically connected to a lower conductive layer of the capacitor 9h described below and the gate electrode of the drive TFT 9d, and the fourth terminal electrode of the initialization TFT 9a is electrically connected to the power source line 22g.

As illustrated in FIG. 4, in each subpixel P, the gate electrode of the compensation TFT 9b is electrically connected to the gate line 12g(n) of the own stage (n-th stage), the third terminal electrode of the compensation TFT 9b is electrically connected to the gate electrode of the drive TFT 9d, and the fourth terminal electrode of the compensation TFT 9b is electrically connected to the first terminal electrode of the drive TFT 9d.

As illustrated in FIG. 4, in each subpixel P, the gate electrode of the write TFT 9c is electrically connected to the gate line 12g(n) of the own stage (n-th stage), the first terminal electrode of the write TFT 9c is electrically connected to the corresponding source line 22f, and the second terminal electrode of the write TFT 9c is electrically connected to the second terminal electrode of the drive TFT 9d.

As illustrated in FIG. 4, in each subpixel P, the gate electrode of the drive TFT 9d is electrically connected to each of the third terminal electrodes of the initialization TFT 9a and the compensation TFT 9b, the first terminal electrode of the drive TFT 9d is electrically connected to the fourth terminal electrode of the compensation TFT 9b and the second terminal electrode of the power supply TFT 9e, and the second terminal electrode of the drive TFT 9d is electrically connected to the second terminal electrode of the write TFT 9c and the first terminal electrode of the light-emission control TFT 9f. Here, the drive TFT 9d is configured to control the current of the organic EL element 35. Since the first gate insulating film 13 is thicker than the second gate insulating film 19 in the first TFT 9A constituting the drive TFT 9d, it is possible to increase an S value of the sub-threshold region in the Id-Vg characteristics and make the rising curved line less steep. As a result, in the first TFT 9A, the amount of change in current with respect to the amount of change in voltage can be reduced, whereby the change in luminance of the organic EL element 35 can be suppressed, and appropriate TFT characteristics can be obtained for the drive TFT 9d.

As illustrated in FIG. 4, in each subpixel P, the gate electrode of the power supply TFT 9e is electrically connected to the light emission control line 12e of the own stage (n-th stage), the first terminal electrode of the power supply TFT 9e is electrically connected to the power source line 22g, and the second terminal electrode of the power supply TFT 9e is electrically connected to the first terminal electrode of the drive TFT 9d.

As illustrated in FIG. 4, in each subpixel P, the gate electrode of the light-emission control TFT 9f is electrically connected to the light emission control line 12e of the own stage (n-th stage), the first terminal electrode of the light-emission control TFT 9f is electrically connected to the second terminal electrode of the drive TFT 9d, and the second terminal electrode of the light-emission control TFT 9f is electrically connected to a first electrode 31 described below of the organic EL element 35.

As illustrated in FIG. 4, in each subpixel P, the gate electrode of the anode discharge TFT 9g is electrically connected to the gate line 12g(n) of the own stage (n-th stage), the third terminal electrode of the anode discharge TFT 9g is electrically connected to the first electrode 31 of the organic EL element 35, and the fourth terminal electrode of the anode discharge TFT 9g is electrically connected to the second initialization power source line 20i.

The capacitor 9h includes, for example, the lower conductive layer (not illustrated) formed of the same material and in the same layer as the second gate electrode 20a, the third interlayer insulating film 21 provided to cover the lower conductive layer, and an upper conductive layer (not illustrated) provided on the third interlayer insulating film 21 to overlap the lower conductive layer and formed of the same material and in the same layer as the first terminal electrode 22a. As illustrated in FIG. 4, in each subpixel P, the lower conductive layer of the capacitor 9h is electrically connected to the gate electrode of the drive TFT 9d and each of the third terminal electrodes of the initialization TFT 9a and the compensation TFT 9b, the upper conductive layer of the capacitor 9h is electrically connected to the third terminal electrode of the anode discharge TFT 9g, the second terminal electrode of the light-emission control TFT 9f, and the first electrode 31 of the organic EL element 35.

The flattening film 23 has a flat surface in the display region D, and is formed of, for example, an organic resin material such as a polyimide resin or an acrylic resin, or a polysiloxane-based spin on glass (SOG) material. As illustrated in FIG. 3, the flattening film 23 is provided on the third interlayer insulating film 21 to cover the first terminal electrodes 22a, the second terminal electrodes 22b, the third terminal electrodes 22c, and the fourth terminal electrodes 22d.

As illustrated in FIG. 3, the organic EL element layer 40 includes a plurality of the organic EL elements 35 provided as a plurality of the light-emitting elements to be arrayed in a matrix shape corresponding to the plurality of subpixels P, and edge covers 32 provided in a lattice pattern common to all the subpixels P in such a manner as to cover a peripheral end portion of the first electrode 31 of each organic EL element 35.

As illustrated in FIG. 3, the organic EL element 35 includes, in each subpixel P, the first electrode 31 provided on the flattening film 23 of the TFT layer 30a, the organic EL layer 33 provided on the first electrode 31, and a second electrode 34 provided on the organic EL layer 33.

The first electrode 31 is electrically connected to the second terminal electrode of the light-emission control TFT 9f of each of the subpixels P, through a contact hole formed in the flattening film 23. Further, the first electrode 31 functions to inject holes (positive holes) into the organic EL layer 33. Further, the first electrode 31 is preferably formed of a material having a large work function to improve the efficiency of hole injection into the organic EL layer 33. Here, examples of materials constituting the first electrode 31 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Examples of the materials constituting the first electrode 31 may include alloy such as astatine (At)/astatine oxide (AtO₂). Furthermore, examples of the materials constituting the first electrode 31 may include electrically conductive oxide such as tin oxide (SnO), zinc oxide (ZnO), indium tin oxide (ITO), and indium zinc oxide (IZO). Additionally, the first electrode 31 may be formed by layering a plurality of layers formed of any of the materials described above. Note that examples of compound materials having a high work function include indium tin oxide (ITO) and indium zinc oxide (IZO).

As illustrated in FIG. 5, the organic EL layer 33 includes a hole injection layer 1, a hole transport layer 2, a light-emitting layer 3, an electron transport layer 4, and an electron injection layer 5, which are sequentially provided on the first electrode 31.

The hole injection layer 1 is also referred to as an anode buffer layer, and functions to reduce an energy level difference between the first electrode 31 and the organic EL layer 33 to thereby improve the efficiency of hole injection into the organic EL layer 33 from the first electrode 31. Here, examples of materials constituting the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 functions to improve the efficiency of hole transport from the first electrode 31 to the organic EL layer 33. Here, examples of materials constituting the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where holes and electrons are injected from the first electrode 31 and the second electrode 34, respectively, and the holes and the electrons recombine, in a case where a voltage is applied via the first electrode 31 and the second electrode 34. Here, the light-emitting layer 3 is formed of a material having high luminous efficiency. Moreover, examples of materials constituting the light-emitting layer 3 include metal oxinoid compounds (8-hydroxyquinoline metal complexes), naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 has a function of facilitating migration of electrons to the light-emitting layer 3 efficiently. Here, examples of materials constituting the electron transport layer 4 include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds, as organic compounds.

The electron injection layer 5 functions to reduce an energy level difference between the second electrode 34 and the organic EL layer 33 to thereby improve the efficiency of electron injection into the organic EL layer 33 from the second electrode 34, and this function allows the drive voltage of the organic EL element 35 to be reduced. Note that the electron injection layer 5 is also referred to as a cathode buffer layer. Here, examples of materials constituting the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂), aluminum oxide (Al₂O₃), and strontium oxide (SrO).

As illustrated in FIG. 3, the second electrode 34 is provided in common to all the subpixels P to cover each organic EL layer 33 and each edge cover 32. Further, the second electrode 34 functions to inject electrons into the organic EL layer 33. Further, the second electrode 34 is preferably formed of a material having a low work function to improve the efficiency of electron injection into the organic EL layer 33. Here, examples of a material constituting the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Further, the second electrode 34 may be formed of alloy such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), and lithium fluoride (LiF)/calcium (Ca)/aluminum (Al). Further, the second electrode 34 may be formed of an electrically conductive oxide such as tin oxide (SnO), zinc oxide (ZnO), indium tin oxide (ITO), and indium zinc oxide (IZO). Further, the second electrode 34 may be formed by layering a plurality of layers formed of any of the materials described above. Note that examples of materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

The edge cover 32 is formed of, for example, an organic resin material such as a polyimide resin or an acrylic resin, or an SOG material of a polysiloxane based.

As illustrated in FIG. 3, the sealing film 45 is provided to cover the second electrode 34, includes a first inorganic sealing film 41, an organic sealing film 42, and a second inorganic sealing film 43 sequentially layered on the second electrode 34, and has a function to protect the organic EL layer 33 of the organic EL element layer 35 from moisture and oxygen.

The first inorganic sealing film 41 and the second inorganic sealing film 43 are formed of, for example, an inorganic insulating film such as a silicon nitride film, a silicon oxide film, or a silicon oxynitride film.

The organic sealing film 42 is formed of, for example, an organic resin material such as an acrylic resin, an epoxy resin, a silicone resin, a polyurea resin, a parylene resin, a polyimide resin, or a polyamide resin.

In the organic EL display device 50 having the configuration described above, in each subpixel P, the organic EL element 35 is brought into a non-light emission state in a case where the light emission control line 12e is selected to be in a non-active state. In the non-light emission state, the gate line 12g(n−1) of the previous stage is selected, and a gate signal is input to the initialization TFT 9a via the gate line 12g(n−1), so that the initialization TFT 9a is brought into an on state, the high power supply voltage ELVDD of the power source line 22g is applied to the capacitor 9h, and the drive TFT 9d is brought into the on state. Thereby, the charge of the capacitor 9h is discharged to initialize the voltage applied to the gate electrode of the drive TFT 9d. Subsequently, the gate line 12g(n) of the own stage is selected and activated, so that the compensation TFT 9b and the write TFT 9c are brought into the on state. Then, a predetermined voltage corresponding to a source signal transmitted via the corresponding source line 22f is written to the capacitor 9h via the drive TFT 9d in the diode-connected state and the anode discharge TFT 9g is brought into the on state, and an initialization signal is applied to the first electrode 31 of the organic EL element 35 via the second initialization power source line 20i to reset the charge accumulated in the first electrode 31. Thereafter, the light emission control line 12e is selected, and the power supply TFT 9e and the light-emission control TFT 9f are brought into the on state, so that a drive current corresponding to the voltage applied to the gate electrode of the drive TFT 9d is supplied to the organic EL element 35 from the power source line 22g. In this way, in the organic EL display device 50, in each subpixel P, the organic EL element 35 emits light at a luminance corresponding to the drive current, and the image display is performed.

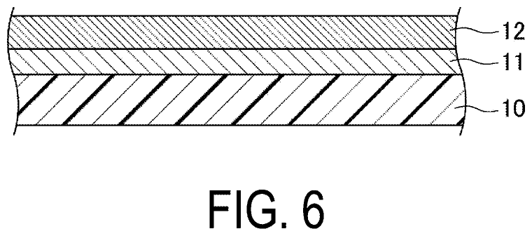

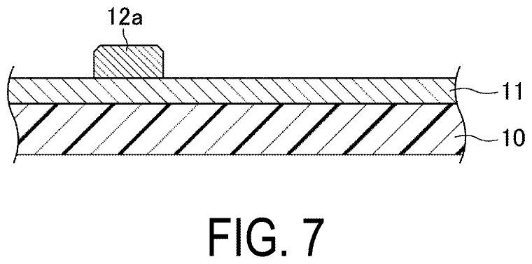

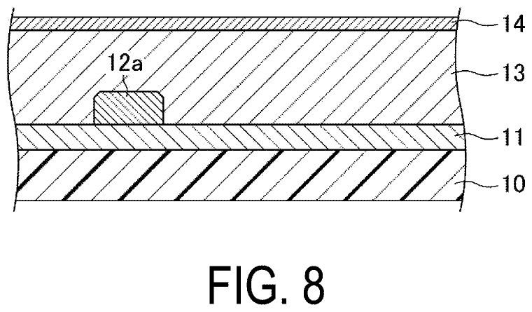

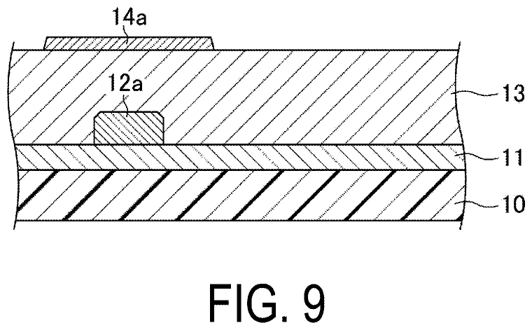

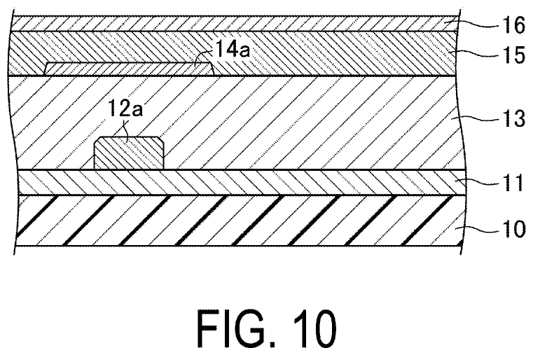

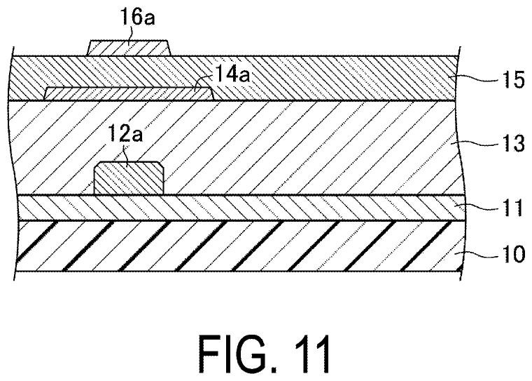

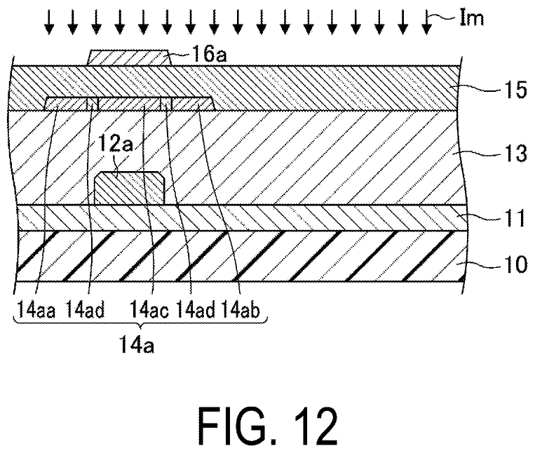

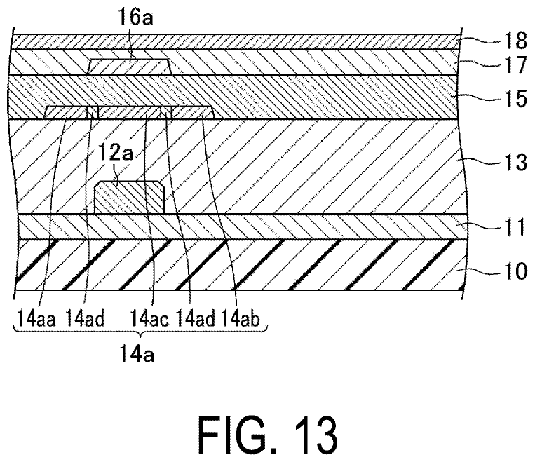

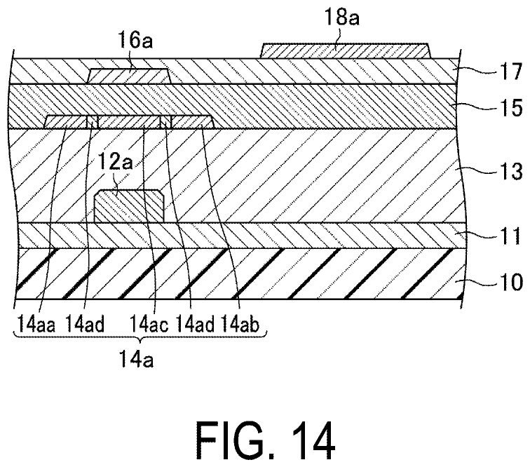

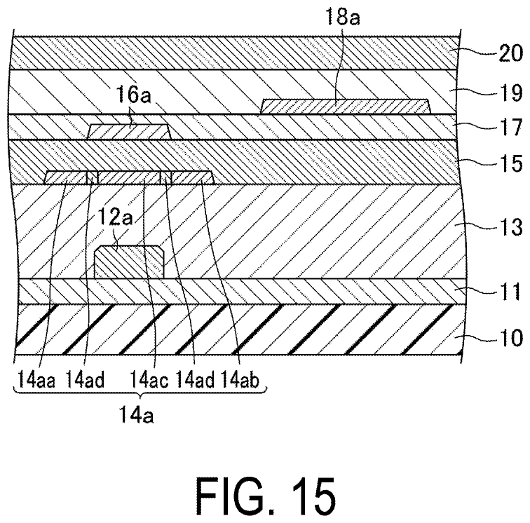

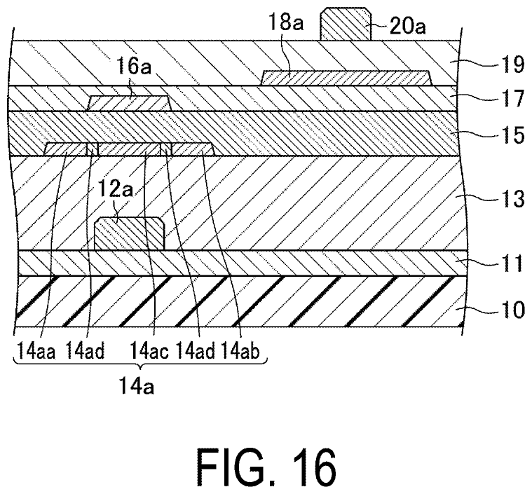

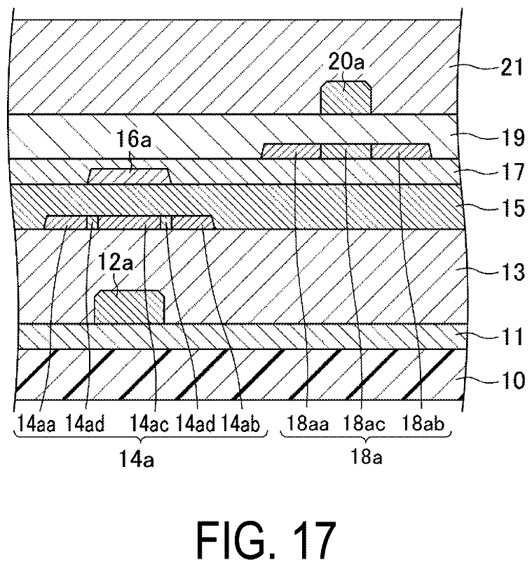

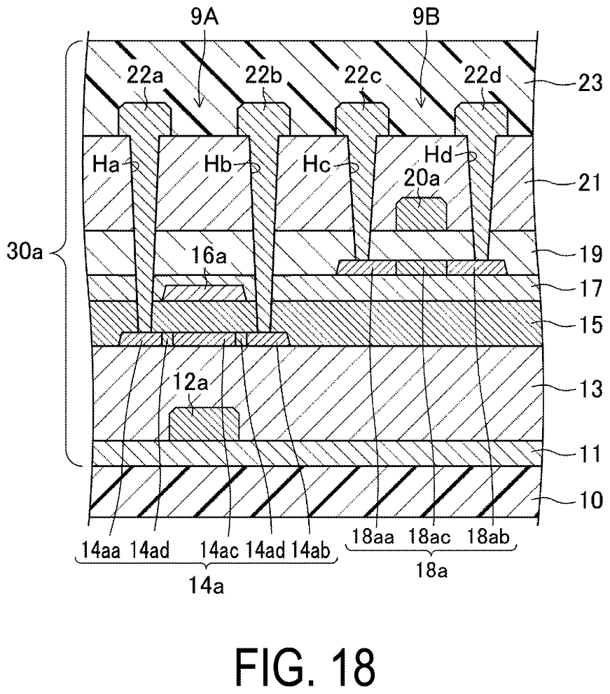

Next, a method for manufacturing the organic EL display device 50 according to the present embodiment will be described. Note that the manufacturing method for the organic EL display device 50 includes a TFT layer forming step, an organic EL element layer forming step, and a sealing film forming step. FIG. 6, FIG. 7, FIG. 8, FIG. 9, FIG. 10, FIG. 11, FIG. 12, FIG. 13, FIG. 14, FIG. 15, FIG. 16, FIG. 17, and FIG. 18 are first, second, third, fourth, fifth, sixth, seventh, eighth, ninth, tenth, eleventh, twelfth, and thirteenth cross-sectional views for sequentially depicting the TFT layer forming step constituting the method for manufacturing the organic EL display device of the present embodiment.

TFT Layer Forming Step First, for example, a silicon oxide film (with a thickness of approximately 100 nm) is formed by, for example, a plasma chemical vapor deposition (CVD) method, on the resin substrate 10 formed on a glass substrate, thereby forming the base coat film 11.

Subsequently, as illustrated in FIG. 6, a metal film 12 such as a molybdenum film (with a thickness of approximately 200 nm) is formed by, for example, a sputtering method, on the substrate surface where the base coat film 11 is formed, and then the metal film 12 is patterned by dry etching to form the first gate electrode 12a as illustrated in FIG. 7. When the first gate electrode 12a is formed, the gate line 12g, the light emission control line 12e, and the like are also formed.

Thereafter, a silicon oxide film (approximately 100 nm in thickness), a silicon nitride film (approximately 30 nm in thickness), and a silicon oxide film (approximately 250 nm in thickness) are formed in sequence by, for example, the plasma CVD method, on the substrate surface where the first gate electrode 12a and the like are formed, thereby forming the first gate insulating film 13.

Furthermore, for example, an amorphous silicon film (with a thickness of approximately 50 nm) is formed by, for example, the plasma CVD method, on the substrate surface where the first gate insulating film 13 is formed, and the amorphous silicon film is crystallized by laser annealing or the like to form a polysilicon film 14 as depicted in FIG. 8, and then the polysilicon film 14 is patterned to form the first semiconductor layer 14a as depicted in FIG. 9.

Thereafter, as illustrated in FIG. 10, the first interlayer insulating film 15 is formed by film-forming a silicon oxide film (approximately 100 nm) by, for example, the plasma CVD method, on the substrate surface where the first semiconductor layer 14a is formed, and further a metal film 16 such as a molybdenum film (approximately 100 nm in thickness) is formed by the sputtering method. Thereafter, the metal film 16 is patterned by wet etching to form the metal layer 16a, as depicted in FIG. 11.

Subsequently, as illustrated in FIG. 12, by doping with impurity ions Im while using the metal layer 16a as a mask, a part of the first semiconductor layer 14a is made conductive to form the first conductor region 14aa, the second conductor region 14ab, the first channel region 14ac, and the low concentration impurity regions 14ad in the first semiconductor layer 14a. In this case, end faces of both end portions of the metal layer 16a on the first conductor region 14aa side and the second conductor region 14ab side are inclined in a tapered shape in such a manner as to gradually project from a side opposite to the resin substrate 10 toward the resin substrate 10 side, so that both the end portions of the metal layer 16a are formed thinner than the intermediate portion thereof. As a result, the first conductor region 14aa side and the second conductor region 14ab side of the first channel region 14ac are doped with the impurity ions Im at a lower concentration than in the first conductor region 14aa and the second conductor region 14ab in correspondence with both the end portions of the metal layer 16a.

Then, as illustrated in FIG. 13, the second interlayer insulating film 17 is formed by film-forming a silicon oxide film (approximately 50 nm) by, for example, the plasma CVD method, on the substrate surface where a part of the first semiconductor layer 14a is made conductive. Further, an oxide semiconductor film 18 such as an InGaZnO₄ film (approximately 30 nm in thickness) is formed by the sputtering method, and then the oxide semiconductor film 18 is patterned to form the second semiconductor layer 18a as illustrated in FIG. 14.

Thereafter, a silicon oxide film (with a thickness of approximately 100 nm) is formed by, for example, the plasma CVD method, on the substrate surface where the second semiconductor layer 18a is formed, thereby forming the second gate insulating film 19.

Further, as illustrated in FIG. 15, a metal film 20 such as a molybdenum film (with a thickness of approximately 200 nm) is formed by, for example, the sputtering method, on the substrate surface where the second gate insulating film 19 is formed, and then the metal film 20 is patterned by dry etching to form the second gate electrode 20a as illustrated in FIG. 16. Note that in a case where the second gate electrode 20a is formed, the second initialization power source line 20i is also formed.

Subsequently, a silicon oxide film (approximately 300 nm in thickness) and a silicon nitride film (approximately 150 nm in thickness) are formed in sequence by, for example, the plasma CVD method, on the substrate surface where the second gate electrode 20a is formed, thereby forming the third interlayer insulating film 21 as illustrated in FIG. 17. A part of the second semiconductor layer 18a is made conductive by heat treatment after the formation of the third interlayer insulating film 21, so that the third conductor region 18aa, the fourth conductor region 18ab, and the second channel region 18ac are formed in the second semiconductor layer 18a.

Thereafter, in the substrate surface where the third interlayer insulating film 21 is formed, the first interlayer insulating film 15, the second interlayer insulating film 17, the second gate insulating film 19, and the third interlayer insulating film 21 are appropriately patterned to form contact holes such as the first contact hole Ha, the second contact hole Hb, the third contact hole Hc, and the fourth contact hole Hd.

Further, a titanium film (with a thickness of approximately 50 nm), an aluminum film (with a thickness of approximately 400 nm), a titanium film (with a thickness of approximately 50 nm), and the like are sequentially formed by, for example, the sputtering method, on the substrate surface where the contact holes such as the first contact hole Ha are formed. Thereafter, the metal layered film thereof is patterned to form the first terminal electrode 22a, the second terminal electrode 22b, the third terminal electrode 22c, and the fourth terminal electrode 22d. When the first terminal electrode 22a, the second terminal electrode 22b, the third terminal electrode 22c, and the fourth terminal electrode 22d are formed, the source line 22f and the power source line 22g are also formed.

Finally, a polyimide-based photosensitive resin film (with a thickness of approximately 2 μm) is applied by, for example, a spin coating method or a slit coating method, onto the substrate surface where the first terminal electrode 22a and the like are formed. Thereafter, pre-baking, exposing, developing, and post-baking are performed on the applied film to form the flattening film 23 as illustrated in FIG. 18.

As described above, the TFT layer 30a can be formed.

### Organic EL Element Layer Forming Step

The organic EL element layer 40 is formed by forming the first electrode 31, the edge cover 32, the organic EL layer 33 (the hole injection layer 1, the hole transport layer 2, the light-emitting layer 3, the electron transport layer 4, the electron injection layer 5), and the second electrode 34 on the flattening film 23 of the TFT layer 30a having been formed in the TFT layer forming step, by using a known method.

### Sealing Film Forming Step

First, an inorganic insulating film such as a silicon nitride film, a silicon oxide film, or a silicon oxynitride film is formed by plasma CVD method on a substrate surface formed with the organic EL element layer 40 formed in the organic EL element layer forming step by using a mask to form the first inorganic sealing film 41.

Next, on the substrate surface formed with the first inorganic sealing film 41, a film made of an organic resin material such as acrylic resin is formed by, for example, using an ink-jet method to form the organic sealing film 42.

Thereafter, an inorganic insulating film such as a silicon nitride film, a silicon oxide film, or a silicon oxynitride film is formed by plasma CVD method on the substrate surface formed with the organic sealing film 42 by using a mask to form the second inorganic sealing film 43, thereby forming the sealing film 45.

Finally, after a protective sheet (not illustrated) is applied to the substrate surface formed with the sealing film 45, the glass substrate is peeled off from the lower face of the resin substrate 10 by irradiation with laser light from the glass substrate side of the resin substrate 10, and then a protective sheet (not illustrated) is applied to the lower face of the resin substrate 10, from which the glass substrate has been peeled off.

The organic EL display device 50 of the present embodiment can be manufactured in the manner described above.

As described above, according to the organic EL display device 50 of the present embodiment, since the first gate electrode 12a is provided on the resin substrate 10 side of the first semiconductor layer 14a formed of polysilicon via the first gate insulating film 13 in the first TFT 9A, influence of the impurity ions in the resin substrate 10 on the first semiconductor layer 14a may be blocked by the first gate electrode 12a. In addition, since the metal layer 16a is provided on the opposite side to the resin substrate 10 side of the first semiconductor layer 14a via the first interlayer insulating film 15 in such a manner as to overlap with the first channel region 14ac, it is possible to make it difficult for the charge generated during the manufacturing process to enter the first channel region 14ac of the first semiconductor layer 14a. This makes it possible to stabilize the characteristics of the first TFT 9A, and therefore in the organic EL display device 50 having the hybrid structure using the resin substrate 10, the characteristics of the first TFT 9A using the polysilicon semiconductor can be stabilized and the display quality can be improved.

According to the organic EL display device 50 of the present embodiment, the end faces of both the end portions of the metal layer 16a on the first conductor region 14aa side and the second conductor region 14ab side are inclined in a tapered shape in such a manner as to gradually project from the side opposite to the resin substrate 10 toward the resin substrate 10 side, whereby both the end portions of the metal layer 16a are formed thinner than the intermediate portion thereof. Because of this, the low concentration impurity regions 14ad containing the impurity ions Im at a lower concentration than in the first conductor region 14aa and the second conductor region 14ab are respectively provided at the first conductor region 14aa side and the second conductor region 14ab side of the first channel region 14ac in correspondence with both the end portions of the metal layer 16a. Furthermore, the width of the metal layer 16a along the channel length direction is made larger than the width of the first gate electrode 12a along the channel length direction, so that the low concentration impurity regions 14ad are disposed inside the first gate electrode 12a. This reduces the off-current of the first TFT 9A using the polysilicon semiconductor, so that the first TFT 9A suitable for the drive TFT 9d can be constituted.

According to the organic EL display device 50 of the present embodiment, since the first TFT 9A is a bottom gate type and the second TFT 9B is a top gate type, it is possible to reduce parasitic capacitance generated between the first gate electrode 12a of the first TFT 9A and the second gate electrode 20a of the second TFT 9B, and parasitic capacitance generated between the first gate electrode 12a of the first TFT 9A and the second TFT 9B. Furthermore, since the first gate electrode 12a of the first TFT 9A and the second gate electrode 20a of the second TFT 9B are spaced apart from each other in the thickness direction, it is possible to suppress short circuit failure at a portion where the first gate electrode 12a of the first TFT 9A and the wiring lines formed of the same material and in the same layer as the first gate electrode 12a, and the second gate electrode 20a of the second TFT 9B and the wiring lines formed of the same material and in the same layer as the second gate electrode 20a intersect with one another.

According to the organic EL display device 50 of the present embodiment, since the first gate insulating film 13 is thicker than the second gate insulating film 19, it is possible to increase the S value of the sub-threshold region in the Id-Vg characteristics and make the rising curved line less steep. As a result, in the first TFT 9A, the amount of change in current with respect to the amount of change in voltage can be reduced, whereby the change in luminance of the organic EL element 35 can be suppressed, and appropriate TFT characteristics can be obtained for the drive TFT 9d. Furthermore, by adjusting the thicknesses of the first gate insulating film 13 and the second gate insulating film 19, imbalance caused by a difference in characteristics between the first TFT 9A using the polysilicon semiconductor and the second TFT 9B using the oxide semiconductor can be eliminated, thereby making it possible to increase the degree of design freedom.

According to the organic EL display device 50 of the present embodiment, since the base coat film 11 made of an inorganic insulating film is provided between the resin substrate 10 and the first gate electrodes 12a, film peeling of the first gate electrode 12a and the like may be suppressed.

### Second Embodiment

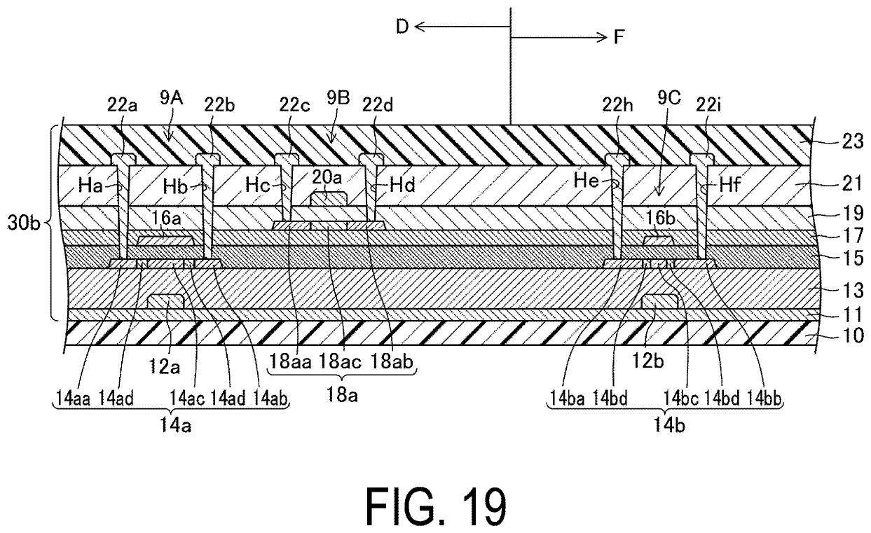

FIG. 19 illustrates a second embodiment of a display device according to the disclosure. Here, FIG. 19 is a cross-sectional view of a thin film transistor layer 30b constituting an organic EL display device of the present embodiment. In the following embodiments, the same portions as those in FIG. 1 to FIG. 18 are denoted by the same reference signs, and detailed description thereof will be omitted.

In the first embodiment, the organic EL display device 50 including the TFT layer 30a, in which the first TFT 9A using the polysilicon semiconductor and the second TFT 9B using the oxide semiconductor are provided in the display region D, is exemplified. However, in the present embodiment, the organic EL display device including a TFT layer 30b, in which a third TFT 9C using a polysilicon semiconductor is provided in a frame region F in addition to a first TFT 9A and a second TFT 9B being provided in a display region D, will be exemplified.

Similar to the organic EL display device 50 of the first embodiment described above, the organic EL display device of the present embodiment includes the display region D provided in a rectangular shape and the frame region F provided around the display region D, for example.

The organic EL display device of the present embodiment includes a resin substrate 10, the TFT layer 30b (see FIG. 19) provided on the resin substrate 10, an organic EL element layer 40 provided on the TFT layer 30b, and a sealing film 45 provided to cover the organic EL element layer 40.

As illustrated in FIG. 19, the TFT layer 30b includes a base coat film 11 provided on the resin substrate 10; four first TFTs 9A, three second TFTs 9B, and one capacitor 9h (see FIG. 4) provided on the base coat film 11 for each subpixel P; a plurality of the third TFTs 9C provided on the base coat film 11 in the frame region F; and a flattening film 23 provided on each first TFT 9A, each second TFT 9B, each capacitor 9h, and each third TFT 9C. In this case, similar to the TFT layer 30a of the first embodiment described above, the TFT layer 30b is provided with a plurality of gate lines 12g, a plurality of light emission control lines 12e, a plurality of second initialization power source lines 20i, a plurality of source lines 22f, and a plurality of power source lines 22g.

As illustrated in FIG. 19, the third TFT 9C includes a third gate electrode 12b provided on the base coat film 11; a first gate insulating film 13 provided to cover the third gate electrode 12b; a third semiconductor layer 14b provided on the first gate insulating film 13; a first interlayer insulating film 15 provided on the third semiconductor layer 14b; a frame metal layer 16b provided on the first interlayer insulating film 15; a second interlayer insulating film 17, a second gate insulating film 19, and a third interlayer insulating film 21 provided in sequence on the frame metal layer 16b; and a fifth terminal electrode 22h and a sixth terminal electrode 22i provided to be separated from each other on the third interlayer insulating film 21.

As illustrated in FIG. 19, the third gate electrode 12b is provided on the base coat film 11 to overlap a third channel region 14bc described below of the third semiconductor layer 14b, and is configured to control conduction between a fifth conductor region 14ba and a sixth conductor region 14bb to be described below of the third semiconductor layer 14b. In other words, as illustrated in FIG. 19, the third gate electrode 12b is provided on the resin substrate 10 side (lower side in the drawing) of the third channel region 14bc via the first gate insulating film 13. As illustrated in FIG. 19, the third gate electrode 12b has the same thickness and the same cross-sectional shape as a first gate electrode 12a and a second gate electrode 20a. The third gate electrode 12b is formed of the same material and in the same layer as the first gate electrode 12a and the signal wiring lines such as the gate lines 12g and the light emission control lines 12e.

The third semiconductor layer 14b is formed of, for example, polysilicon such as LTPS, and as illustrated in FIG. 19, includes the fifth conductor region 14ba and the sixth conductor region 14bb defined to be separated from each other, the third channel region 14bc defined between the fifth conductor region 14ba and the sixth conductor region 14bb, and a pair of low concentration impurity regions 14bd respectively provided at the fifth conductor region 14ba side of the third channel region 14bc and the sixth conductor region 14bb side thereof. The low concentration impurity regions 14bd are regions that are provided corresponding to end faces described below of both end portions on the fifth conductor region 14ba side and the sixth conductor region 14bb side of the frame metal layer 16b, and contain impurities at a concentration lower than that of the fifth conductor region 14ba and the sixth conductor region 14bb; that is, they are a so-called LDD region. A part of the third semiconductor layer 14b is doped with phosphorus, boron, or the like as the impurity ions Im. In the present embodiment, for example, a complementary metal oxide semiconductor (CMOS) is constituted as a drive circuit (gate driver) by combining an n-channel third TFT 9C doped with phosphorus and a p-channel third TFT 9C doped with boron.

As illustrated in FIG. 19, the frame metal layer 16b is provided on the opposite side to the resin substrate 10 side of the third semiconductor layer 14b in such a manner as to overlap the third channel region 14bc via the first interlayer insulating film 15. As illustrated in FIG. 19, the end faces of both the end portions of the frame metal layer 16b on the fifth conductor region 14ba side and the sixth conductor region 14bb side are inclined in a tapered shape in such a manner as to gradually project from the side opposite to the resin substrate 10 (the upper side in the drawing) toward the resin substrate 10 side (the lower side in the drawing). In this case, angles formed by the end faces of both the end portions of the frame metal layer 16b and the substrate surface are each, for example, approximately 20° to 40°. The film thickness of the frame metal layer 16b is, for example, approximately 100 nm, and is smaller than the film thickness of the first gate electrode 12a and the second gate electrodes 20a (for example, approximately 200 nm), as illustrated in FIG. 19. As illustrated in FIG. 19, a width along the channel length direction (horizontal direction in the drawing) of the frame metal layer 16b is smaller than a width along the channel length direction (horizontal direction in the drawing) of the third gate electrode 12b. The frame metal layer 16b is electrically connected to the third gate electrode 12b. As illustrated in FIG. 19, the second interlayer insulating film 17 is provided on the frame metal layer 16b to cover the frame metal layer 16b.

As illustrated in FIG. 19, the fifth terminal electrode 22h and the sixth terminal electrode 22i are provided on the opposite side to the resin substrate 10 side (upper side in the drawing) of the frame metal layer 16b, and are electrically connected to the fifth conductor region 14ba and the sixth conductor region 14bb, respectively, of the third semiconductor layer 14b through a fifth contact hole He and a sixth contact hole Hf formed in the layered film of the first interlayer insulating film 15, the second interlayer insulating film 17, the second gate insulating film 19, and the third interlayer insulating film 21.

In the organic EL display device of the present embodiment, as in the organic EL display device 50 of the above-described first embodiment, in each subpixel P, an organic EL element 35 emits light at a level of luminance corresponding to the drive current, thereby performing image display.

The organic EL display device of the present embodiment may be manufactured in the following manner: in the TFT layer forming step in the method for manufacturing the organic EL display device 50 of the first embodiment discussed above, the third gate electrode 12b is also formed when the first gate electrode 12a is formed, the third semiconductor layer 14b is also formed when the first semiconductor layer 14a is formed, the frame metal layer 16b is also formed when the metal layer 16a is formed, and the fifth terminal electrode 22h and sixth terminal electrode 22i are also formed when the first terminal electrode 22a, second terminal electrode 22b, third terminal electrode 22c, and fourth terminal electrodes 22d are formed.

As described above, according to the organic EL display device of the present embodiment, since the first gate electrode 12a is provided on the resin substrate 10 side of the first semiconductor layer 14a formed of polysilicon via the first gate insulating film 13 in the first TFT 9A, the influence of the impurity ions in the resin substrate 10 on the first semiconductor layer 14a may be blocked by the first gate electrode 12a. In addition, since the metal layer 16a is provided on the opposite side to the resin substrate 10 side of the first semiconductor layer 14a via the first interlayer insulating film 15 in such a manner as to overlap with the first channel region 14ac, it is possible to make it difficult for the charge generated during the manufacturing process to enter the first channel region 14ac of the first semiconductor layer 14a. Further, since the third gate electrode 12b is provided on the resin substrate 10 side of the third semiconductor layer 14b formed of polysilicon via the first gate insulating film 13 in the third TFT 9C, the influence of the impurity ions in the resin substrate 10 on the third semiconductor layer 14b may be blocked by the third gate electrode 12b. In addition, since the frame metal layer 16b is provided on the opposite side to the resin substrate 10 side of the third semiconductor layer 14b via the first interlayer insulating film 15 in such a manner as to overlap with the third channel region 14bc, it is possible to make it difficult for the charge generated during the manufacturing process to enter the third channel region 14bc of the third semiconductor layer 14b. This makes it possible to stabilize the characteristics of the first TFT 9A and the third TFT 9C, and therefore in the organic EL display device having the hybrid structure using the resin substrate 10, the characteristics of the first TFT 9A and third TFT 9C using the polysilicon semiconductor can be stabilized and the display quality can be improved.

According to the organic EL display device of the present embodiment, the end faces of both the end portions of the metal layer 16a on the first conductor region 14aa side and the second conductor region 14ab side are inclined in a tapered shape in such a manner as to gradually project from the side opposite to the resin substrate 10 toward the resin substrate 10 side, whereby both the end portions of the metal layer 16a are formed thinner than the intermediate portion thereof. Because of this, the low concentration impurity regions 14ad containing the impurity ions Im at a lower concentration than in the first conductor region 14aa and the second conductor region 14ab are respectively provided at the first conductor region 14aa side and the second conductor region 14ab side of the first channel region 14ac in correspondence with both the end portions of the metal layer 16a. This reduces the off-current of the first TFT 9A using the polysilicon semiconductor, so that the first TFT 9A suitable for the drive TFT 9d can be constituted.

According to the organic EL display device of the present embodiment, the end faces of both the end portions of the frame metal layer 16b on the fifth conductor region 14ba side and the sixth conductor region 14bb side are inclined in a tapered shape in such a manner as to gradually project from the side opposite to the resin substrate 10 toward the resin substrate 10 side, whereby both the end portions of the frame metal layer 16b are formed thinner than the intermediate portion thereof. Because of this, the low concentration impurity regions 14bd containing the impurity ions Im at a lower concentration than in the fifth conductor region 14ba and the sixth conductor region 14bb are respectively provided at the fifth conductor region 14ba side and the sixth conductor region 14bb side of the third channel region 14bc in correspondence with both the end portions of the frame metal layer 16b. Furthermore, the width of the frame metal layer 16b along the channel length direction is made smaller than the width of the third gate electrode 12b along the channel length direction, so that the low concentration impurity regions 14bd are disposed inside the third gate electrode 12b. As a result, the electric field concentration in the fifth conductor region 14ba and the sixth conductor region 14bb of the third TFT 9C using the polysilicon semiconductor is suppressed, so that the third TFT 9C suitable for the gate driver can be constituted.

According to the organic EL display device of the present embodiment, since the frame metal layer 16b is electrically connected to the third gate electrodes 12b in the third TFT 9C, the third TFT 9C has a double gate structure, thereby making it possible to enhance the drive capability of the third TFT 9C.

According to the organic EL display device of the present embodiment, since the first TFT 9A is a bottom gate type and the second TFT 9B is a top gate type, it is possible to reduce parasitic capacitance generated between the first gate electrode 12a of the first TFT 9A and the second gate electrode 20a of the second TFT 9B, and parasitic capacitance generated between the first gate electrode 12a of the first TFT 9A and the second TFT 9B. Furthermore, since the first gate electrode 12a of the first TFT 9A and the second gate electrode 20a of the second TFT 9B are spaced apart from each other in the thickness direction, it is possible to suppress short circuit failure at a portion where the first gate electrode 12a of the first TFT 9A and the wiring lines formed of the same material and in the same layer as the first gate electrode 12a, and the second gate electrode 20a of the second TFT 9B and the wiring lines formed of the same material and in the same layer as the second gate electrode 20a intersect with one another.

According to the organic EL display device of the present embodiment, since the first gate insulating film 13 is thicker than the second gate insulating film 19, it is possible to increase the S value of the sub-threshold region in the Id-Vg characteristics and make the rising curved line less steep. As a result, in the first TFT 9A, the amount of change in current with respect to the amount of change in voltage can be reduced, whereby the change in luminance of the organic EL element 35 can be suppressed, and appropriate TFT characteristics can be obtained for the drive TFT 9d. Furthermore, by adjusting the thicknesses of the first gate insulating film 13 and the second gate insulating film 19, imbalance caused by a difference in characteristics between the first TFT 9A using the polysilicon semiconductor and the second TFT 9B using the oxide semiconductor can be eliminated, thereby making it possible to increase the degree of design freedom.

According to the organic EL display device of the present embodiment, since the base coat film 11 made of an inorganic insulating film is provided between the resin substrate 10 and the first gate electrodes 12a, film peeling of the first gate electrode 12a and the like may be suppressed.

### OTHER EMBODIMENTS

In each of the embodiments described above, the organic EL layer having a five-layer structure including the hole injection layer, the hole transport layer, the light-emitting layer, the electron transport layer, and the electron injection layer is exemplified, but the organic EL layer may have a three-layer structure including a hole injection-cum-transport layer, a light-emitting layer, and an electron transport-cum-injection layer, for example.

In each of the embodiments described above, the organic EL display device including the first electrode as an anode and the second electrode as a cathode is exemplified. The disclosure is also applicable to an organic EL display device in which the layered structure of the organic EL layer is reversed with the first electrode being a cathode and the second electrode being an anode.

In each of the embodiments described above, the organic EL display device is exemplified as the display device, but the disclosure is also applicable to, for example, a display device such as a liquid crystal display device employing an active matrix driving method.

In each of the embodiments described above, the organic EL display device is exemplified as a display device. The disclosure can also be applied to a display device including a plurality of light-emitting elements driven by a current, for example, to a display device including quantum-dot light emitting diodes (QLEDs), which are a light-emitting element using a quantum dot-containing layer.

### INDUSTRIAL APPLICABILITY

As described above, the disclosure is useful for a flexible display device.

1. A display device, comprising:
a resin substrate, and
a thin film transistor layer provided on the resin substrate,
wherein, in the thin film transistor layer, a first thin film transistor including a first semiconductor layer formed of polysilicon and a second thin film transistor including a second semiconductor layer formed of an oxide semiconductor are provided for each of subpixels constituting a display region,
the first thin film transistor includes
the first semiconductor layer in which a first conductor region and a second conductor region are defined to be separated from each other and a first channel region is defined between the first conductor region and the second conductor region,
a first gate electrode provided on the resin substrate side of the first channel region via a first gate insulating film,
a metal layer provided on a side opposite to the resin substrate side of the first semiconductor layer to overlap the first channel region via a first interlayer insulating film, and
a first terminal electrode and a second terminal electrode provided to be separated from each other on a side opposite to the resin substrate of the metal layer and electrically connected to the first conductor region and the second conductor region, respectively, and
the second thin film transistor includes
the second semiconductor layer which is provided at a position farther from the resin substrate relative to the first semiconductor layer and in which a third conductor region and a fourth conductor region are defined to be separated from each other,
a second gate electrode provided on a side opposite to the resin substrate of the second semiconductor layer via a second gate insulating film, and
a third terminal electrode and a fourth terminal electrode provided to be separated from each other on a side opposite to the resin substrate of the second gate electrode and electrically connected to the third conductor region and the fourth conductor region, respectively.

2. The display device according to claim 1,
wherein end faces of both end portions of the metal layer on the first conductor region side and the second conductor region side are inclined in a tapered shape in such a manner as to gradually project from a side opposite to the resin substrate toward the resin substrate side.

3. The display device according to claim 2,
wherein low concentration impurity regions containing impurities at a concentration lower than a concentration in the first conductor region and the second conductor region are respectively provided at the first conductor region side and the second conductor region side of the first channel region in correspondence with the end faces of both the end portions of the metal layer on the first conductor region side and the second conductor region side.

4. The display device according to claim 2,
wherein a film thickness of the metal layer is smaller than a film thickness of the second gate electrode.

5. The display device according to claim 2,
wherein a width along a channel length direction of the metal layer is larger than a width along the channel length direction of the first gate electrode.

6. The display device according to claim 5,
wherein the metal layer is electrically floating.

7. The display device according to claim 1,
wherein a third thin film transistor including a third semiconductor layer formed of polysilicon is provided in the thin film transistor layer in a frame region around the display region, and
the third thin film transistor includes
the third semiconductor layer in which a fifth conductor region and a sixth conductor region are defined to be separated from each other and a third channel region is defined between the fifth conductor region and the sixth conductor region,
a third gate electrode provided on the resin substrate side of the third channel region via the first gate insulating film,
a frame metal layer provided on the opposite side to the resin substrate side of the third semiconductor layer in such a manner as to overlap the third channel region via the first interlayer insulating film, and
a fifth terminal electrode and a sixth terminal electrode provided on the opposite side to the resin substrate of the frame metal layer to be separated from each other and electrically connected to the fifth conductor region and the sixth conductor region, respectively.

8. The display device according to claim 7,
wherein end faces of both end portions of the frame metal layer on the fifth conductor region side and the sixth conductor region side are inclined in a tapered shape in such a manner as to gradually project from a side opposite to the resin substrate toward the resin substrate side.

9. The display device according to claim 8,
wherein frame low concentration impurity regions containing impurities at a concentration lower than a concentration in the fifth conductor region and the sixth conductor region are respectively provided at the fifth conductor region side and the sixth conductor region side of the third channel region in correspondence with the end faces of both the end portions of the frame metal layer on the fifth conductor region side and the sixth conductor region side.

10. The display device according to claim 8,
wherein a film thickness of the frame metal layer is smaller than the film thickness of the second gate electrode.

11. The display device according to claim 8,
wherein a width along a channel length direction of the frame metal layer is smaller than a width along the channel length direction of the third gate electrode.

12. The display device according to claim 11,
wherein the frame metal layer is electrically connected to the third gate electrode.

13. The display device according to claim 12,
wherein a film thickness of the first gate insulating film is larger than a film thickness of the first interlayer insulating film.

14. The display device according to claim 1,
wherein the first gate electrode and the second gate electrode have an identical film thickness and an identical cross-sectional shape.

15. The display device according to claim 14,
wherein the first gate electrode and a signal wiring line are formed of an identical material and formed in an identical layer, and
the second gate electrode and another signal wiring line are formed of an identical material and formed in an identical layer.

16. The display device according to claim 1,
wherein a second interlayer insulating film is provided on the metal layer to cover the metal layer,
the second semiconductor layer is provided on the second interlayer insulating film,
a third interlayer insulating film is provided on the second gate electrode to cover the second gate electrode,
the first terminal electrode, the second terminal electrode, the third terminal electrode, and the fourth terminal electrode are provided on the third interlayer insulating film,
the first terminal electrode and the second terminal electrode are electrically connected to the first conductor region and the second conductor region, respectively, through a first contact hole and a second contact hole formed in a layered film of the first interlayer insulating film, the second interlayer insulating film, the second gate insulating film, and the third interlayer insulating film, and
the third terminal electrode and the fourth terminal electrode are electrically connected to the third conductor region and the fourth conductor region, respectively, through a third contact hole and a fourth contact hole formed in a layered film of the second gate insulating film and the third interlayer insulating film.

17. The display device according to claim 1,
wherein a base coat film is provided on the resin substrate, and
the first gate electrode is provided on the base coat film.

18. The display device according to claim 1,
wherein the thin film transistor layer includes a flattening film provided to cover the first terminal electrode, the second terminal electrode, the third terminal electrode, and the fourth terminal electrode.

19. The display device according to claim 1, further comprising:
a light-emitting element layer which is provided on the thin film transistor layer and in which a plurality of light-emitting elements are arrayed; and
a sealing film provided to cover the light-emitting element layer.

20. The display device according to claim 19,
wherein each of the plurality of light-emitting elements is an organic electroluminescence element.
